(19) United States
(12) Patent Application Publication
(10) Pub. No.: US 2007/0246837 A1
(43) Pub. Date: Oct. 25, 2007

(54) IC chip package with minimized packaged-volume

(76) Inventor: Wen-Chang Dong, Banciao City (TW)

Correspondence Address: BACON & THOMAS, PLLC, 625 SLATERS LANE, FOURTH FLOOR, ALEXANDRIA, VA, 22314, US

(21) Appl. No.: 11/785,452

(22) Filed: Apr. 18, 2007

(30) Foreign Application Priority Data
Apr. 20, 2006 (TW) 095114186

(51) Int. Cl. H01L 23/48

(52) U.S. Cl. 257/778

(57) ABSTRACT

An IC chip package, including a single chip package, two stacked chips package or a System-In-Package (SIP), is created to minimize the assembled volume, which basic structure comprises a chip, a circuited substrate provided for the chip electrically mounted thereon and an encapsulated means for covering the chip to constitute a package structure, wherein the chip has a processed substrate with an active side and an inactive side and one or more half-tunneling electrical contacts penetrating the processed substrate to form one or more electrical contacts on the inactive side of the chip, so that the chip is directly through the inactive side of the processed substrate electrically mounted to the circuited substrate without via bonding wires.

### BACKGROUND OF THE INVENTION

1. Field of the Invention

The present invention relates to an IC chip package, more particularly to an IC chip package with minimized packaged-volume.

2. Description of the Prior Art

Referring now to FIG. 1, a traditional method for producing a semiconductor integrated circuit (IC) comprises the steps of:
(a) providing a semiconductor substrate 01;
(b) forming at least one first unit 02a of a semiconductor element 02 on an active side of the semiconductor substrate 01 of the step (a), wherein the first unit 02a is selected from the group consisting of at least one electrode, at least one ion implantation region, and at least one diffusion unit;
(c) forming at least one second unit 02b on an element layer 03 already superimposed on the semiconductor substrate 01 to constitute a semiconductor element 02, wherein the second unit 02b is selected from the group consisting of at least one other electrode, and at least one other unit;
(d) forming at least one circuit 06 and at least one electrical contact 05 on a dielectric layer (or circuit layer) 04 already superimposed on the element layer 03 for being electrically connected to the semiconductor element 02 and then to constitute a complete chip 10; and
(e) connecting the electrical contact 05 formed on the chip 10 to at least one other electrical circuit or element (not shown), and then assembling the chip 10 and the electrical circuit or element into a package structure.

Referring back to FIG. 1, the chip 10 manufactured by said traditional manufacturing method has a basic structure provided with electrical circuits, electrical elements and electrical contacts on an active side of the chip 10, and on an inactive side of the chip 10 is only a bare surface of the semiconductor substrate 01 without any electrical contacts, so that the electrical circuits or other electrically conductive paths of the chip 10 do not be electrically connected from the active side to the inactive side.

As a result, the traditional package structure of the chip 10 is electrically connected to at least one other electrical circuit via the active side of the chip 10 only, but the inactive side thereof is never electrically connected to the electrical circuit.

For example, a traditional package structure 08 (i.e. IC) of a single chip 10 (i.e. single die) is illustrated in FIG. 2a, the chip 10 has an inactive side attached to a metal lead-frame 09, and an active side provided with electrical contacts 05 for being electrically connected to the metal lead-frame 09 via bonding wires 07, so that the chip 10 and the metal lead-frame 09 constitute the traditional package structure 08 of the single chip 10.

For example, a flip-chip package structure 08 of a single chip 10 is illustrated in FIG. 2b, the chip 10 has an active side facing toward and mounted on a circuited substrate 11, wherein the active side is provided with electrical contacts 05 for being electrically connected to electrical contacts 11a of the circuited substrate 11 via solder bumps 12.

For example, a traditional System-In-Package (SIP) structure 08 of two chips 10 is illustrated in FIG. 3a, each of the two chips 10 has an inactive side attached to a common circuited substrate 11, and an active side provided with electrical contacts 05 for being electrically connected to electrical contacts 11a of the circuited substrate 11 via bonding wires 07, so that the two chips 10 and the circuited substrate 11 constitute the single SIP structure 08 of the two chips 10. Because the two chips 10 are mounted on the same circuited substrate 11 of the SIP structure 08, the transmission distance between the two chips 10 will be shortened for enhancing the transmission efficiency thereof.

For example, a traditional flip-chip System-In-Package (SIP) structure 08 of two chips 10 is illustrated in FIG. 3b, each of the two chips 10 has an active side provided with electrical contacts 05 for being electrically connected to electrical contacts 11a of the circuited substrate 11 via flip-chip structures, such as solder bumps, so that the two chips 10 and the circuited substrate 11 constitute the single SIP structure 08 of the two chips 10.

For example, a traditional package-in-package (PIP) structure 08 of two chips 10 is illustrated in FIG. 4a. Firstly, one of the two chips 10 is electrically connected to a circuited substrate 11 by bonding wires 07, and encapsulated to form a single package 08a. Then, the other of the two chips 10 is stacked on the package 08a, and electrically connected to the same circuited substrate 11 by other bonding wires 07, so as to constitute the single PIP structure 08 of the two chips 10. Because the two chips 10 are stacked together and mounted on the same circuited substrate 11 of the PIP structure 08, the amount of the circuited substrate 11 in use will be reduced, and the thickness of the circuited substrate 11 and an encapsulant (unlabeled) of the PIP structure 08 will be decreased.

For example, a traditional package structure 08 of two stacked chips 10 is illustrated in FIG. 4b, wherein one of the two chips 10 is a flip chip electrically connected to a circuited substrate 11 by solder bumps. Then, the other of the two chips 10 is stacked on the lower chip 10, and electrically connected to the same circuited substrate 11 by bonding wires 07, so as to constitute the single package structure 08 of the two stacked chips 10, wherein one of the two chips 10 is a flip-chip.

As shown in FIGS. 2a to 4b, the traditional chips 10 used by the various package structures 08 have a common disadvantage, i.e., a bare surface of the chips 10 is not provided with any electrical contact.

Thus, when two chips 10 are assembled into a SIP structure, a PIP structure, or a stacked-die package structure, it needs a circuited substrate to electrically connect the two chips 10 to each other. As a result, the amount of the chips 10 stacked together and the assembled thickness of the package structure 08 will be limited due to the use of the circuited substrate 11. Even though the space and the area of a motherboard (not shown) are limited, the assembled thickness of the package structure 08 still cannot be reduced to fit into the space and the area thereof. The causes of the foregoing shortcomings are described in more details as below:

1. The stacked amount of the chips 10 is limited:

As shown in FIG. 4a, if the two chips 10 are electrically connected to each other via the circuited substrate 11, an upper surface of the circuited substrate 11 must be provided with enough electrical contacts 11a to electrically connect to the bonding wires 07. However, because the upper surface of the circuited substrate 11 only has a limited area, the amount of the electrical contacts 11a cannot be substantially increased, which subsequently limiting the amount of the chips 10 that can be stacked into the area.

2. The assembled thickness of the package structure 08 cannot be further reduced:

As shown in FIG. 4b, when the two chips 10 are stacked together, the two chips 10 are electrically connected to each other via the bonding wire 07 and the circuited substrate 11. However, the curved height of the bonding wire 07 and the thickness of the circuited substrate 11 cannot be further reduced, so that the assembled thickness of the package structure 08 cannot be minimized.

To solve the foregoing problems of the traditional stacked-die package structure, various technologies for tunneling into semiconductor-processed substrates are further developed.

Referring now to FIG. 5a, U.S. Pat. No. 6,429,096 discloses a chip 10 that is prepared by forming at least one through-hole 15 extended from at least one electrical contact 05 on an active side of the chip 10 to an inactive side thereof. Then, filling the through-hole 15 with at least one conductive metal 16 is to form at least one tunneling contact 13.

Therefore, referring now to FIG. 5b, the chip 10 manufactured by U.S. Pat. No. 6,429,096 is formed with the tunneling contact 13 extended from the active side of the chip 10 to the inactive side thereof. As a result, the active side and the inactive side of the chip 10 are respectively provided with at least one electrical contact 05a and at least one electrical contact 05b, both of which are electrically connected to each other via the tunneling contact 13 of the chip 10.

Referring now to FIG. 5c, when at least two of the chips 10 as shown in FIG. 5b are vertically stacked together, the tunneling contacts 13 of the chips 10 are electrically connected in parallel to each other via solder material 12, such as solder bumps. Thereby, a plurality of chips 10 vertically stacked and electrically connected in parallel are directly assembled on a common circuited substrate 11.

Referring now to FIG. 6a, U.S. Pat. No. 6,982,487 discloses a chip 10 that is prepared by forming at least one cavity 15a extended from an active side of the chip 10 into a processed substrate 01. Then, the processed substrate 01 is ground from an inactive side of the chip 10 until the cavity 15a is exposed on the ground inactive side. Finally, an inner wall of the cavity 15a is formed with a deposited conductive metal 16.

Referring now to FIG. 6b, U.S. Pat. No. 6,982,487 further discloses a special carrier 19 that is connected to the chip 10, so as to constitute a chip unit 10a, wherein the chip unit 10a has a first side provided with an electrical contact 05a and a second side provided with an electrical contact 05b.

Referring now to FIG. 6c, when at least two of the chip units 10a as shown in FIG. 6b are vertically stacked together, the electrical contact 05a on the first side of one of the chip units 10a are electrically connected to the electrical contact 05b on the second side of another chip unit 10a via solder material 12, such as solder bumps. Thereby, a plurality of the chip units 10a vertically stacked and electrically connected in parallel are directly assembled on a common circuited substrate 11.

Briefly, the electrical contact 05a of the active side of the chip 10 disclosed in U.S. Pat. No. 6,429,096 can be electrically connected to the electrical contact 05b of the inactive side of the chip 10, and the electrical contact 05a of the first side of the chip unit 10a disclosed in U.S. Pat. No. 6,982,487 can be electrically connected to the electrical contact 05b of the second side of the unit 10a.

However, the manufacturing methods of U.S. Pat. No. 6,429,096 and U.S. Pat. No. 6,982,487 still have common disadvantages, which are described in more details as follows:

1. The manufacturing method is difficult and has a risk of damaging the chip 10:

Both of the U.S. Pat. Nos. 6,429,096 and 6,982,487 disclose a drilling process after preparing the chip 10. However, the drilling process must drill a conductive layer (unlabeled) and an element layer (unlabeled) of the chip 10, which increases the risk of damaging the chip 10.

2. A corresponding region under the electrical contacts 05a on the active side of the chip 10 cannot be used to provide other circuits 06 or semiconductor elements 02:

If the corresponding region under the electrical contacts 05a on the active side of the chip 10 is used to provide other circuits 06 or semiconductor elements 02, the circuits 06 or semiconductor elements 02 of the chip 10 will be damaged during the drilling process after preparing the chip 10 described in both of the U.S. Pat. Nos. 6,429,096 and 6,982,487. In this case, referring now to FIG. 7a, in order to prevent the circuit 06 or semiconductor element 02 of the chip 10 from damaging during the drilling process, the circuit 06 or semiconductor element 02 must be suitably laid-out to stay clear of the electrical contacts 05. However, if there are too many electrical contacts 05, the layout of the circuit 06 or semiconductor element 02 of the chip 10 will become more complicated.

3. The chips 10 can only be stacked together by electrically connecting in parallel to each other via the electrical contacts 05:

Referring to FIG. 7b, because the electrical contacts 05 on the active side of one of the chips 10 is vertically aligned with the electrical contacts 05 on the inactive side of one another of the chips 10, the chips 10 can only be stacked together and electrically connected in parallel to each other via the electrical contacts 05. As a result, the chips 10 cannot be assembled by other methods, and thus the application of the chips 10 is limited.

It is therefore tried by the inventor to develop a novel chip structure to solve the problems existing in the traditional chips as described above.

### SUMMARY OF THE INVENTION

The present invention is to provide a method for producing a novel chip structure having one or more electrical contact(s) formed on inactive side of the chip, which basic structure comprises a processed substrate with an active side and an inactive side and one or more half-tunneling electrical contacts penetrated through the processed substrate, and the half-tunneling electrical contact of the chip has a first end exposed on the inactive side of the processed substrate and formed as an electrical contact on the inactive side thereof, and a second end electrically connected to a circuit formed in the chip.

The chip disclosed on the present invention has one or more electrical contacts laid-out on the inactive side and/or the active side of the chip and provides various layouts for electrical connections, so that the created chip(s) of the present invention may be applied to assemble various kinds of IC chip packages, including a single chip package, two stacked chips package or a System-In-Package, to get the advantage of minimizing the assembled volume.

Accordingly, a primary object of the present invention is to provide an IC chip package without bonding wires to minimize the assembled volume, which basic structure comprises a chip, a circuited substrate provided for the chip electrically mounted thereon and an encapsulated means for covering the chip to constitute a package structure, wherein the chip has a processed substrate with an active side and an inactive side and one or more half-tunneling electrical contacts penetrating the processed substrate to form one or more electrical contacts on the inactive side of the chip, so that the chip is directly through the inactive side of the processed substrate electrically mounted to the circuited substrate without via bonding wires.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein:

FIG. 1 is a cross-sectional view of a traditional manufacturing method of a semiconductor integrated circuit (IC);

FIGS. 2a and 2b are cross-sectional views of traditional package structures of a single chip;

FIGS. 3a and 3b are cross-sectional views of traditional System-In-Package (SIP) structures of two chips;

FIG. 4a is a cross-sectional view of a traditional package-in-package (PIP) structure;

FIG. 4b is a cross-sectional view of a traditional package structure of two stacked chips;

FIGS. 5a, 5b, and 5c are cross-sectional views of a traditional package structure of stacked chips described in U.S. Pat. No. 6,429,096;

FIGS. 6a, 6b, and 6c are cross-sectional views of a traditional package structure of stacked chip units described in U.S. Pat. No. 6,982,487;

FIGS. 7a and 7b are a top view and a cross-sectional view of a traditional package structure of stacked chips with disadvantages, respectively;

FIGS. 8a, 8b, 8c, and 8d are cross-sectional views of a manufacturing method of a chip structure with at least one half-tunneling electrical contact according to a preferred embodiment of the present invention;

FIG. 9 is a cross-sectional view of a manufacturing method of a chip structure with at least one half-tunneling electrical contact according to another preferred embodiment of the present invention;

FIGS. 10a and 10b are cross-sectional views of a manufacturing method of a chip structure with at least one half-tunneling electrical contact according to another preferred embodiment of the present invention;

FIGS. 11a, 11b, 11c, 11d, 11e, and 11f are cross-sectional views of various layouts and designs of electrical contacts formed on a chip of the present invention;

FIGS. 12a, 12b, 12c, 12d, and 12e are cross-sectional views of various kinds of an IC chip package for packaging a single chip of the present invention;

FIGS. 13a, 13b, 13c, 13d, and 13e are cross-sectional views of various kinds of an IC chip package for packaging two or more stacked chips of the present invention;

FIGS. 14a, 14b, 14c, and 14d are cross-sectional views of various kinds of a SIP packaged IC chip package of the present invention; and

FIGS. 15a, 15b, and 15c are cross-sectional views of various kinds of an optical IC chip packages of the present invention.

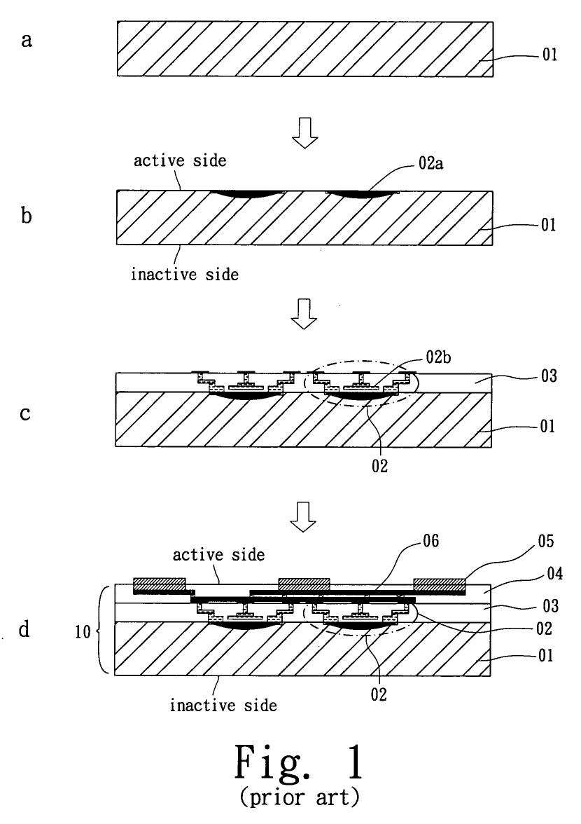

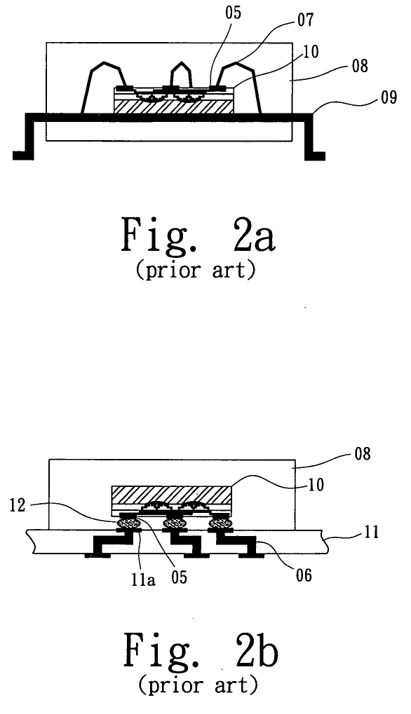

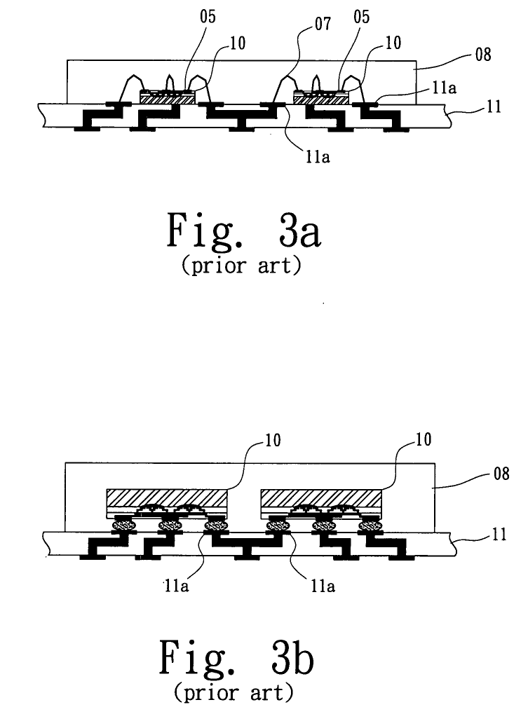

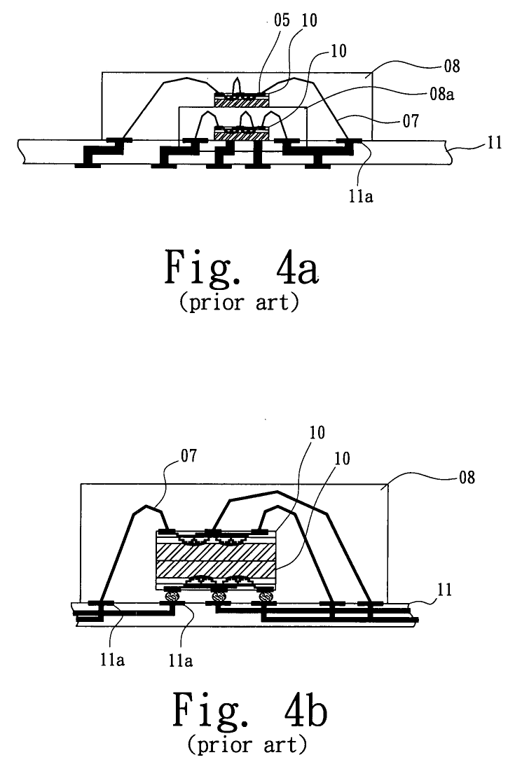

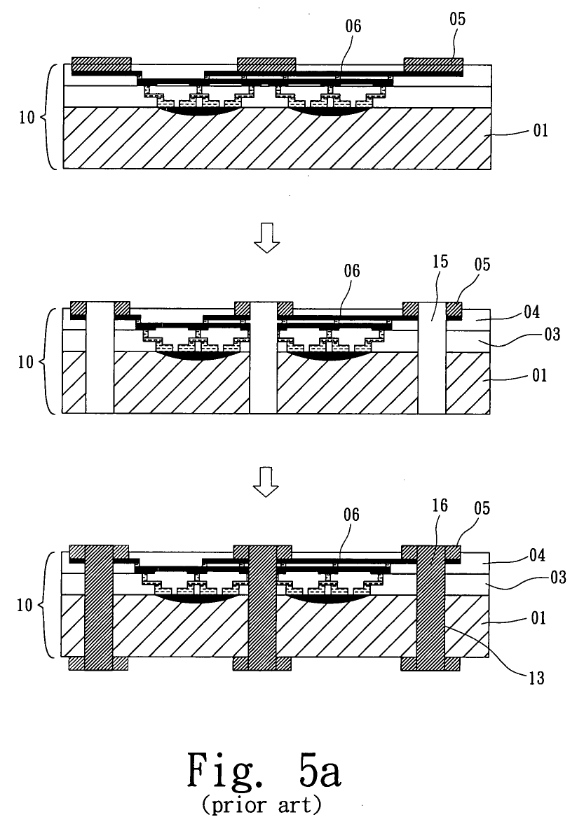

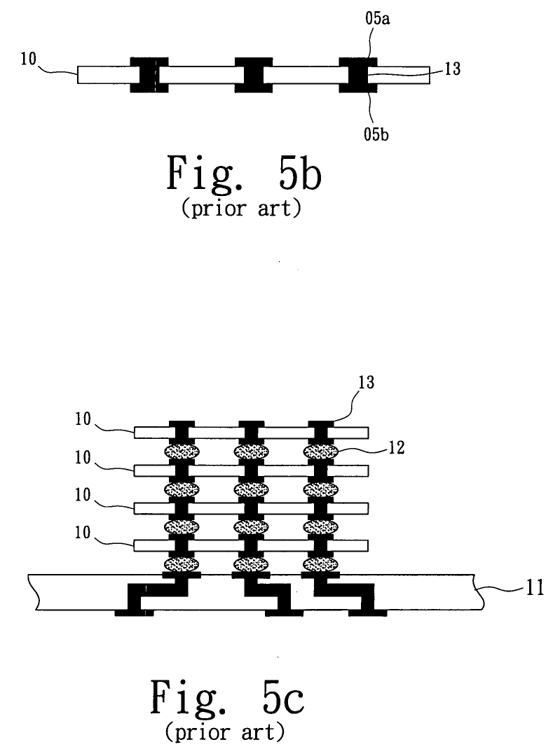

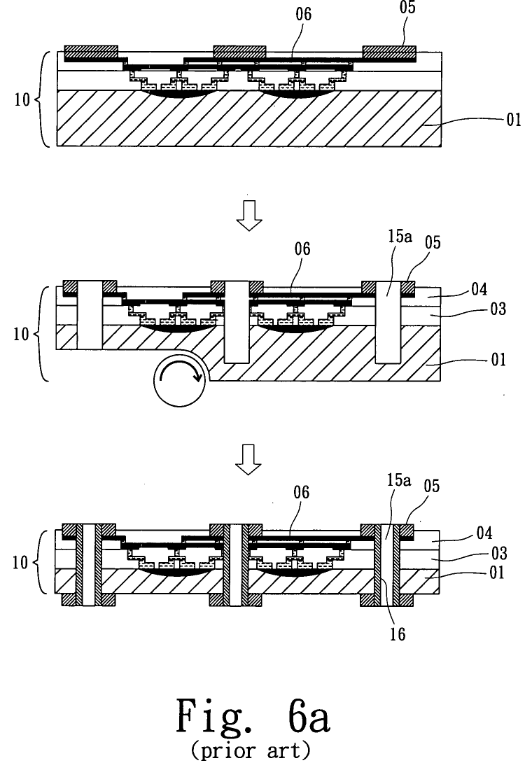

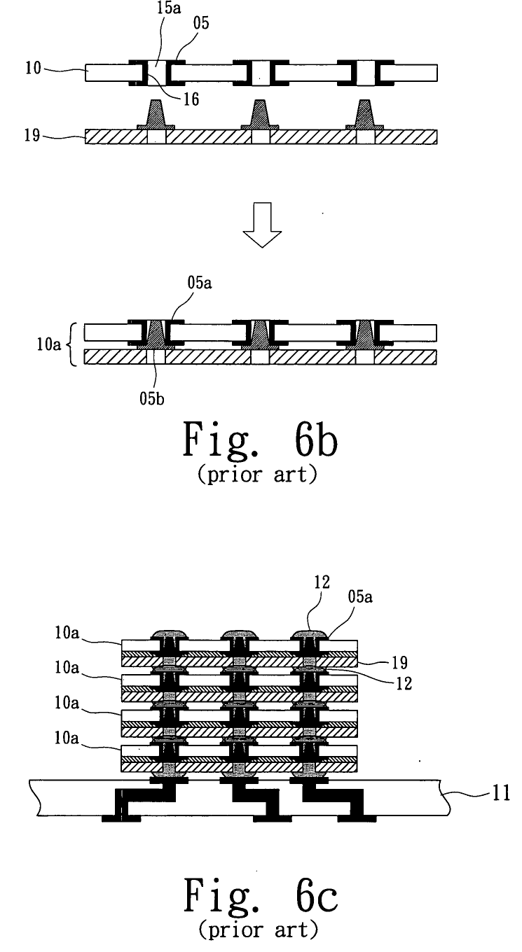

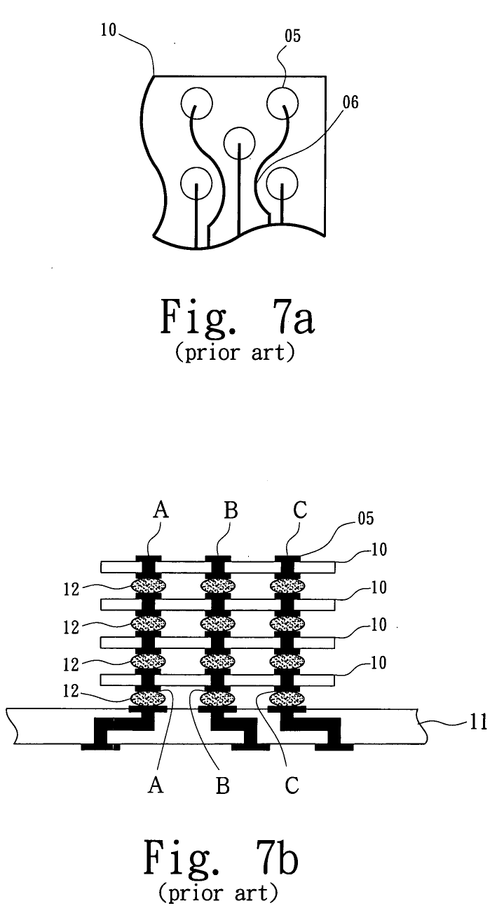

### DETAILED DESCRIPTION OF THE PREFERRED EMBODIMENTS

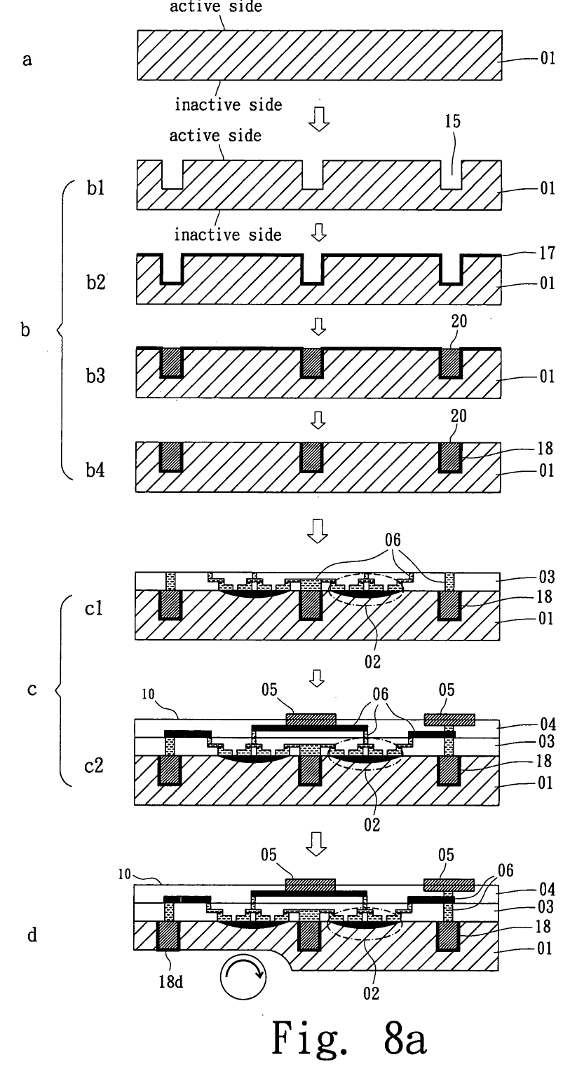

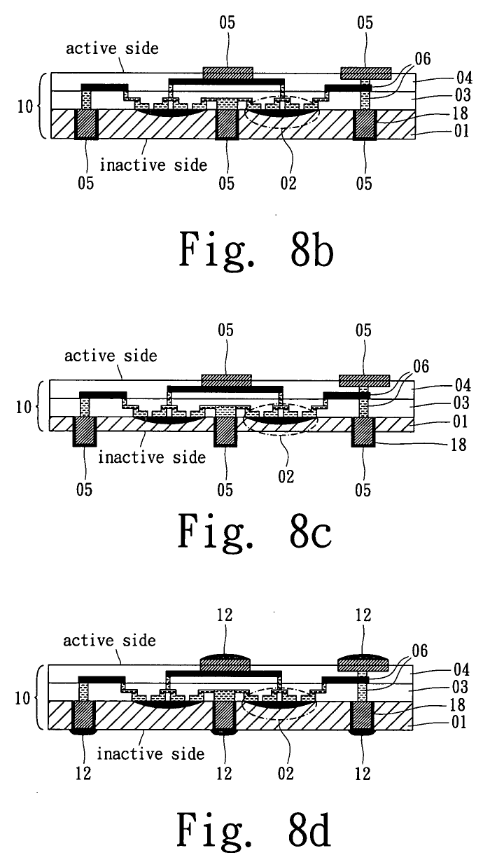

As shown in FIGS. 8a to 11f, a chip 10 of the present invention is fabricated by a semiconductor wafer process. During proceeding with processing the chip 10, a semiconductor substrate (hereinafter, “processed substrate”) 01 is pre-formed with one or more embedded electrical columnar-contacts 18 to be used as an Input/Output terminal of the chip 10 after finishing assembling the chip 10.

And, the embedded electrical columnar-contact 18 of the processed substrate 01 is constituted by always penetrating the processed substrate 01 of the chip 10 but never penetrating the whole chip 10, even through the embedded electrical columnar-contact 18 is further extended from the processed substrate 01 and finally retained to the other layer of the chip 10.

For briefly explaining the requirement limited to the embedded electrical columnar-contact 18 of the processed substrate 01, the embedded electrical columnar-contact 18 is hereinafter referred to as “half-tunneling electrical contact”.

Accordingly, the basic structure of the chip 10 of the present invention has a processed substrate 01 with an active side and an inactive side and one or more half-tunneling electrical contacts 18 penetrating the processed substrate 01. Particularly, each half-tunneling electrical contact 18 of the chip 10 has a first end exposed on the inactive side of the processed substrate 01 to be formed as an electrical contact 05 on the inactive side of the chip 10 and a second end exposed on the active side of the processed substrate 01 which is electrically connected to a circuit 60 formed inside the chip 10.

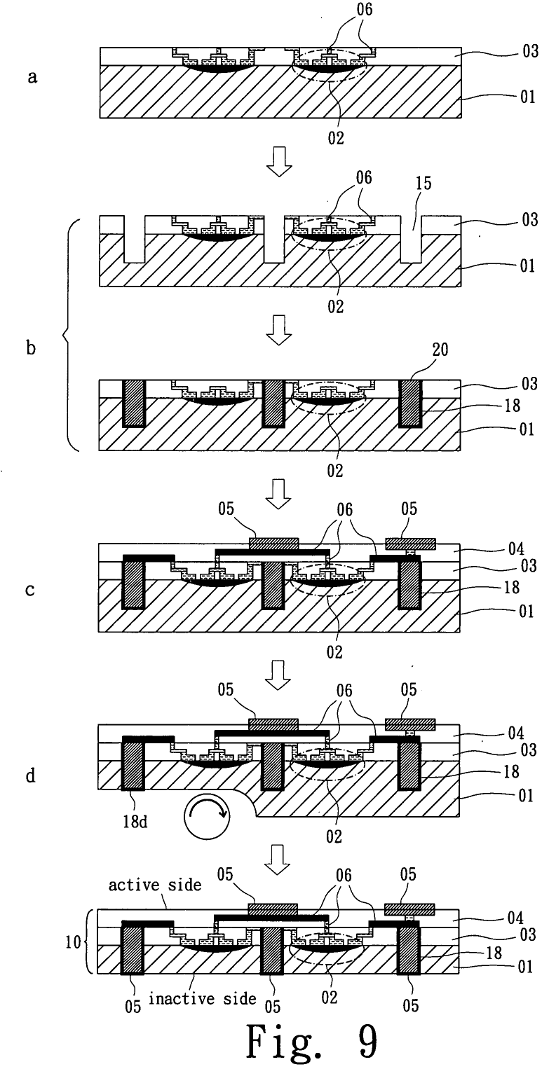

A method for producing the invented chip 10 of the present invention is illustrated in FIG. 8a which comprises the following steps:
(a) providing a processed substrate 01:
   The processed substrate 01 of the present invention is preferably selected from a circuited substrate or a semiconductor substrate made of single crystal silicon, silica, elements of group III, and elements of group V.
   Moreover, the processed substrate 01 as shown in FIG. 8a can be selected from a processed substrate 01 not yet finishing any elements thereon or a processed substrate 01 as shown in FIG. 9 already partially processed one or more semiconductor element 02.
(b) forming one or more half-tunneling electrical contacts 18 penetrating the processed substrate 01 of the step (a), and the step (b) further comprises the following steps:
   (b1) forming at least one cavity 15 on an active side of the processed substrate 01 of the step (a) by semiconductor technologies, such as a semiconductor microlithography and/or an etching technology;
      The cavity 15 has a horizontal cross section selected from a circular shape, a ring shape, or other shapes. Furthermore, except for the semiconductor microlithography or the etching technology, the cavity 15 can be formed by other manufacturing methods, such as a traditionally mechanical process or a laser process.
   (b2) forming at least one pre-formed layer 17, such as a protective layer, an adhesive layer or a seed layer, on a wall surface of the cavity 15 of the step (b1);
   (b3) filling a conductive material 20 into the cavity 15 after finishing the step (b2);
      The conductive material 20 may be selected from the group consisting of nickel, copper, gold, aluminum, tungsten, and alloy thereof. Furthermore, the conductive material 20 can be selected from other conductive metal material or other conductive nonmetal material. The conductive material 20 can be filled into the cavity 15 by a traditional deposition technology, such as physical vapor deposition, chemical vapor deposition, electroplating, or electroless plating (i.e., chemical plating).
   (b4) removing a redundant portion of the pre-formed layer 17 including the protective layer, the adhesive layer and the seed layer, so that a remaining portion of the conductive material 20 filled in the cavity 15 is defined as the half-tunneling electrical contact 18.
(c) forming one or more semiconductor elements 02, related circuits 06 and/or electrical contacts 05 on the active side of the processed substrate 01 after finishing the step (b), and the step (c) further comprises the following steps:
   (c1) forming an element layer 03 on the active side of the processed substrate 01 after finishing the step (b), and then forming the semiconductor element 02 and the related circuit 06 in the element layer 03, wherein the semiconductor element 02 is selected from the group consisting of at least one electrode, at least one ion implantation region, and at least one diffusion unit;
   (c2) forming a dielectric layer 04 on the element layer 03 of the processed substrate 01 after finishing the step (c1), and then forming the other circuit(s) 06 in the dielectric layer 04 and forming the electrical contact(s) 05 on the dielectric layer 04.
(d) removing a portion of the inactive side of the processed substrate 01 after finishing the step (c1) until exposing an end 18d of the half-tunneling electrical contact 18 as an electrical contact of the inactive side of the chip 10.

In the step (d) of the present invention, the portion of the inactive side of the processed substrate 01 of the chip 10 can be removed by mechanical polishing, chemical polishing, various dry etching, various wet etching, other physical etching, or other chemical etching until exposing the pre-formed end 18d of the half-tunneling electrical contact 18.

At step (a) of FIG. 9, when the processed substrate 01 is already partially processed one or more semiconductor element 02, one or more half-tunneling electrical contacts 18 are formed to penetrate both the element layer 03 and the processed substrate 01 at step (b) of FIG. 9, and then the processed substrate 01 is further processed by steps (c) and (d) of FIG. 9 similar to that of FIG. 8a to finish the chip 10.

Therefore, referring back to FIG. 8b, the chip 10 produced by the invented method of the present invention is characterized in that the active side and the inactive side of the chip 10 are respectively provided with one or more electrical contacts 05 and one or more half-tunneling electrical contacts 18 penetrated the processed substrate 01, so that the end of the half-tunneling electrical contact 18 is exposed on the inactive side of the chip 10 and become an electrical contact 05 formed on the inactive side of the chip 10. Furthermore, the other end of the half-tunneling electrical contact 18 penetrated the processed substrate 01 is electrically connected to the circuit 06 formed in the element layer 03 and the dielectric layer 04 of the chip 10.

In comparison with FIG. 8b, another embodiment of the present invention is that the other end of the half-tunneling electrical contact 18 of FIG. 9 is penetrated both the processed substrate 01 and the element layer 03 of the chip 10 and is electrically connected to the circuit 06 formed in the dielectric layer 04 of the chip 10.

In addition, the electrical contact 05 of the chip 10 can be further processed if necessary. Take the chip 10 shown in FIG. 8c or 8d as an example; the electrical contact 05 on the inactive side of the chip 10 may be extended out of the processed substrate 01, alternatively, the electrical contact 05 on the active side and/or the inactive side of the chip 10 may be covered with a solder material 12 for soldering.

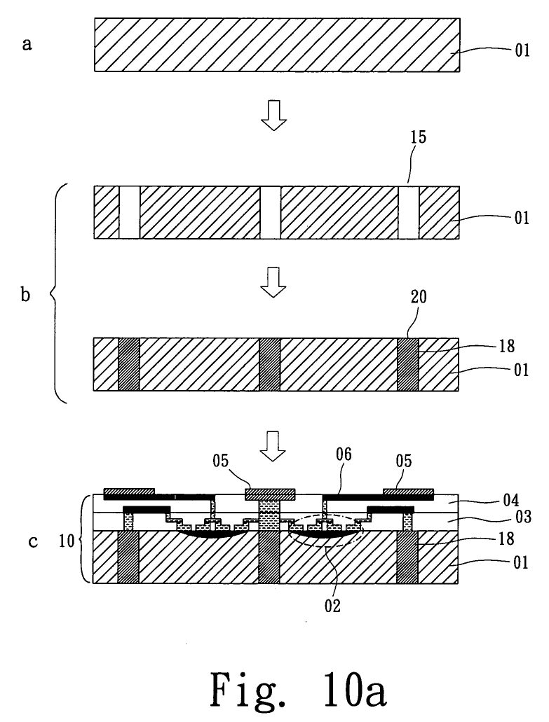

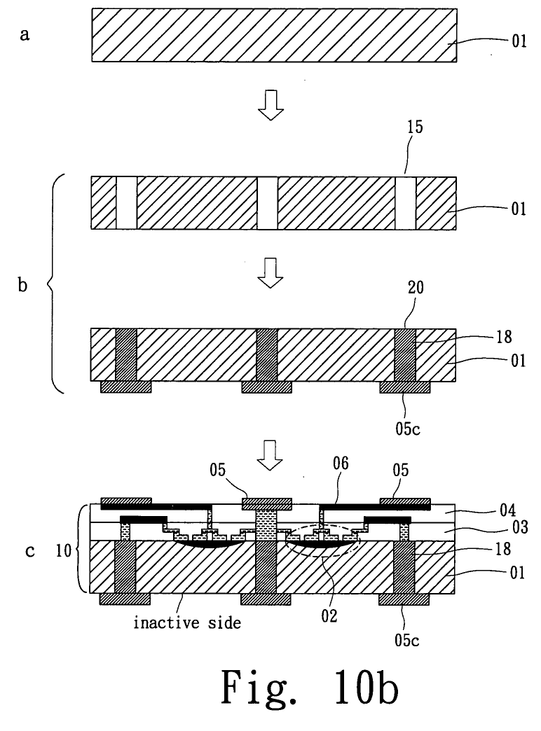

Referring to FIG. 10a, another method for producing the chip 10 of the present invention is to omit the step (d) of FIG. 8a, because at step (b) of FIG. 10a the half-tunneling electrical contact 18 may be directly penetrated the processed substrate 01, and then the processed substrate 01 is further processed by step (c) of FIG. 10a similar to that of FIG. 8a to finish the chip 10.

Referring to FIG. 10b, after a half-tunneling electrical contact 18 is completely formed to penetrate a processed substrate 01 at step (b) of FIG. 10b, an end of the half-tunneling electrical contact 18 exposed on an inactive side of the processed substrate 01 may be further preformed with an electrical contact 05 or other pre-formed structure. Thus, the finished chip 10 can be provided with the electrical contact 05 on an inactive side of the processed substrate 01.

Referring back to FIG. 8a, one pre-formed layer 17, such as the protective layer, the adhesive layer, or the seed layer, is formed on a wall surface of the cavity 15 at step (b) of FIG. 8a, the purpose is that the protective layer (i.e., the pre-formed layer 17) can be used to prevent the conductive material 20 from generating an ion diffusion effect with the processed substrate 01 made of single crystal silicon to ensure the electrical property of the conductive material 20. Moreover, the adhesive layer (i.e., the pre-formed layer 17) can be used to improve the adhesive property of the conductive material 20 for preventing the conductive material 20 from separating from the processed substrate 01 made of single crystal silicon. The seed layer (i.e., the pre-formed layer 17) can be used to improve the electrically conductive property of the surface of the cavity 15 for depositing metal of the conductive material 20 on the surface thereof.

Therefore, the material of the pre-formed layer 17, such as the protective layer, the adhesive layer, or the seed layer, is selected according to the material of the conductive material 20. If the conductive material 20 has no shortcomings as described above, the manufacture of the protective layer or the adhesive layer (i.e., the pre-formed layer 17) at the step (b) of FIG. 8a can be omitted.

Accordingly, the chip 10 of the invention has a novel created structure which is constituted by one or more half-tunneling electrical contacts 18 penetrated through a processed substrate 01 of the chip 10 to have the electrical contact(s) 05 laid-out on the active side or/and the inactive side of the chip 10 or laid-out over/under an element layer 03 and/or a circuit layer 04 of the chip 10.

Particularly, each of the half-tunneling electrical contacts 18 may be designed to be either electrically connected or not electrically connected to an electrical contact 05 formed on an active side of the chip 10. As a result, the chip 10 produced by the above-mentioned manufacturing method may provide various layouts and designs of the electrical contacts 05 according to various needs.

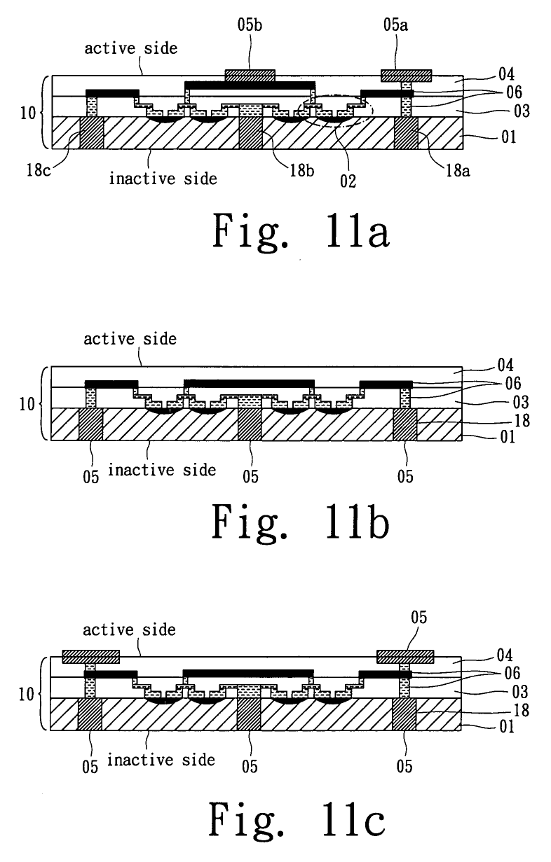

Take the chip 10 shown in FIGS. 11a to 11f as six preferable examples to describe various layouts of the electrical contacts 05 formed on the inactive side and/or the active side of the chip 10.

The chip 10 shown in FIG. 11a is provided with three half-tunneling electrical contacts 18a, 18b, and 18c each penetrated the processed substrate 01 of the chip 10 and provided one end exposed on the inactive side of the processed substrate 01 respectively.

The specific structure of the chip 10 is that the other end of the half-tunneling electrical contact 18a is electrically connected to the electrical contact 05a on the active side of the chip 10 via the circuit 06 formed in the element layer 03 and the dielectric layer 04, the other end of the half-tunneling electrical contact 18b is electrically connected to the electrical contact 05b on the active side of the chip 10 via the semiconductor element 02 of the element layer 03 and the circuit 06 in the dielectric layer 04, and the other end of the half-tunneling electrical contacts 18c is only electrically connected to the circuit 06 formed in the element layer 03 and the dielectric layer 04, but not to the electrical contact 05 formed on active side of the chip 10.

The chip 10 shown in FIG. 11b is provided with a plurality of electrical contacts 05 only exposed on the inactive side of the processed substrate 01 of the chip 10.

The chip 10 shown in FIG. 11c is provided with a plurality of electrical contacts 05 exposed on both the active side and the inactive side of the processed substrate 01 of the chip 10.

The chip 10 shown in FIG. 11d is provided with three half-tunneling electrical contacts 18a, 18b, and 18c, wherein an electrical contact 05b on the active side of the chip 10 is located over the half-tunneling electrical contacts 18b which is also electrically connected to the electrical contact 05b via a circuit 06 vertically designed in the element layer 03 and the dielectric layer 04.

The chip 10 shown in FIG. 11e is provided with three half-tunneling electrical contacts 18a, 18b, and 18c, and three corresponding electrical contact 05a, 05b and 05c on the active side of the chip 10 are respectively located over the corresponding half-tunneling electrical contacts 18a, 18b, and 18c which are also electrically connected to the electrical contact 05a, 05b and 05c via a corresponding circuit 06 vertically designed in the element layer 03 and the dielectric layer 04, respectively.

The chip 10 shown in FIG. 11f has three half-tunneling electrical contacts 18a, 18b, and 18c, each of which is not directly connected to the electrical contact 05a, 05b, and 05c on the active side of the chip 10, respectively.

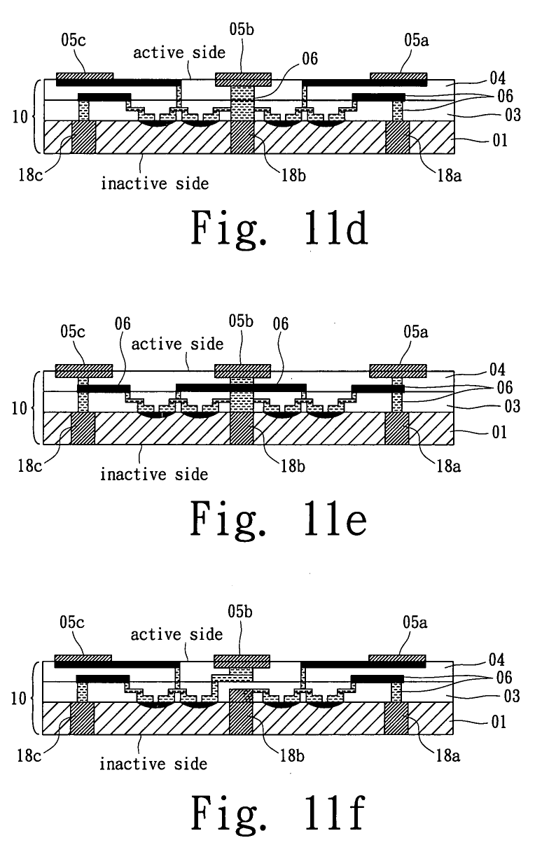

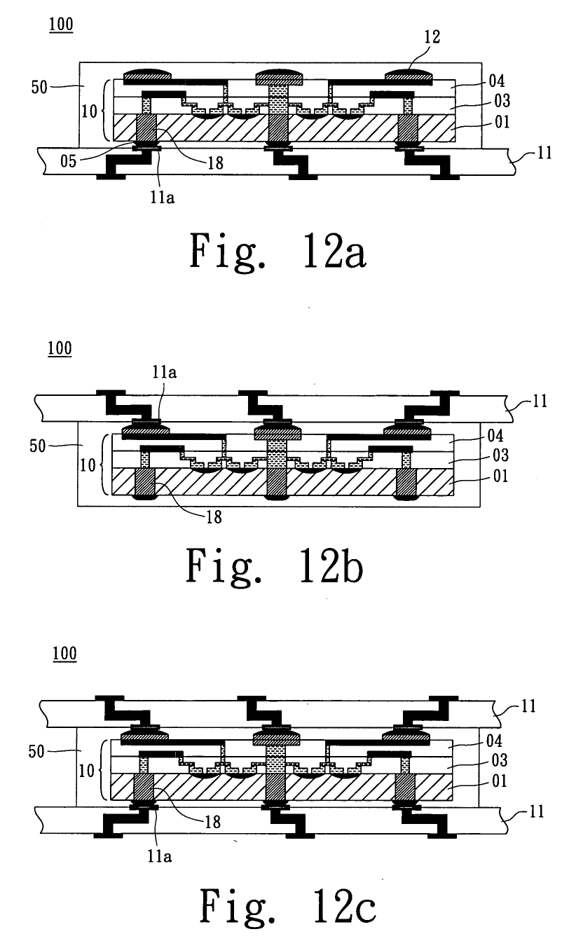

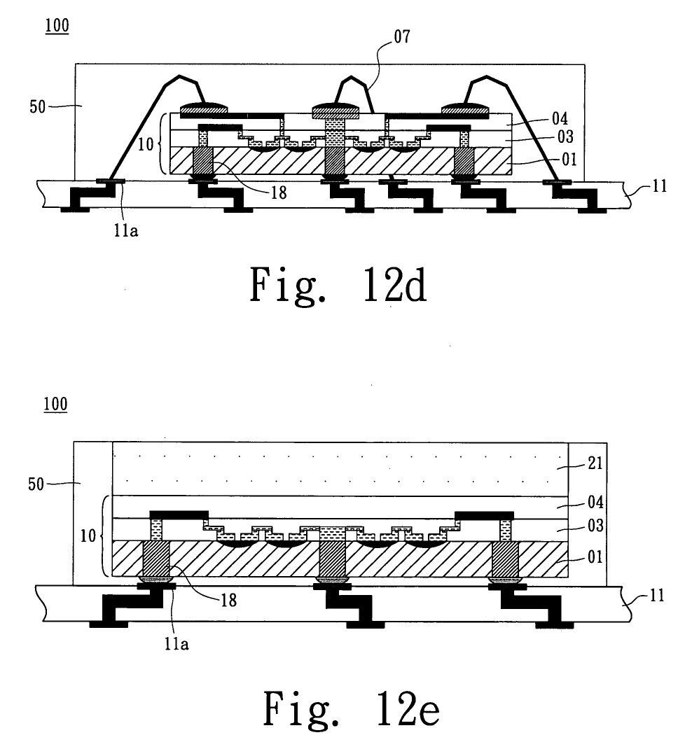

Accordingly, the chip 10 disclosed on the present invention is provided with the structure having one or more electrical contacts 05 laid-out on the active side or the inactive side of the chip 10 and having various layouts for electrical connections, so that the kind of chip 10 of the present invention may be applied to assemble various kinds of IC chip packages 100 as illustrated in FIGS. 12a to 15c.

As a result, one primary advantage from an IC chip packages 100 of the present invention is created to minimize the assembled volume, which basic structure of the IC chip packages 100 at least comprises one or more the above-mentioned chips 10, a circuited substrate (or other element, such as metal lead-frames) 11 provided for the chips 10 electrically mounted thereon and an encapsulated means 50 for covering the chips 10 to constitute a package structure of the IC chip package 100.

Another advantage from the IC chip packages 100 of the present invention is that two or more chips 10 of the present invention are so easily stacked together in parallel or in series electrical connection and assembled into a System-In-Package (SIP) structure without via bonding wires 07 for the purpose of minimizing the assembled volume thereof.

### Embodiments of IC Chip Package for Packaging Single Chip

Five preferred embodiments of IC chip package 100 of the present invention are illustrated in FIGS. 12a to 12e respectively, each kind of IC chip package 100 of the present invention at least comprises a single chip 10 having one or more half-tunneling electrical contacts 18 penetrating a processed substrate 01 for forming one or more electrical contacts 05 on inactive side of the chip 10 or on both inactive side and active side of the chip 10, a circuited substrate (or other element) 11 having a top and bottom surfaces on which conductive circuit patterns formed with electrical contacts 11a are respectively laid-out for providing the chip 10 electrically mounted thereon and an encapsulated means 50 for covering the chip 10 to constitute a package structure of the IC chip package 100.

Further, to minimize the assembled volume, the package structure of the IC chip package 100 illustrated in FIG. 12a is packaged in such a way that the electrical contacts 05 formed on the inactive side of the chip 10 are electrically connected to the corresponding electrical contacts 11a of the circuited substrate (or other element) 11 without via bonding wires.

Likewise, the package structure of the IC chip package 100 illustrated in FIG. 12b is packaged in such a way that the electrical contacts 05 formed on the active side of the chip 10 are electrically connected to the corresponding electrical contacts 11a of the circuited substrate (or other element) 11 without via bonding wires.

Another package structure to minimize the assembled volume of the IC chip package 100 illustrated in FIG. 12c is that a single chip 10 is electrically packaged with two separated circuited substrate (or other element) 11 through the electrical contacts 05 respectively formed on inactive side and active side of the chip 10 to electrically connect to the corresponding electrical contacts 11a of the respective circuited substrate (or other element) 11 without via bonding wires.

Another package structure of the IC chip package 100 illustrated in FIG. 12d is that by different electrical connecting technologies a single chip 10 is electrically packaged with a single circuited substrate (or other element) 11 through the electrical contacts 05 formed on the inactive side of the chip 10 electrically connected to the corresponding electrical contacts 11a of the circuited substrate (or other element) 11 and other electrical contacts 05 formed on the active side of the chip 10 via bonding wires 07 electrically connected to the corresponding electrical contacts 11a of the circuited substrate (or other element) 11.

Another package structure of the IC chip package 100 illustrated in FIG. 12e is that a single chip 10 is packaged with a circuited substrate 11 and an electronic element (or a transparent material) 21 installed over the chip 10 and the circuited substrate 11, wherein the circuited substrate 11 is provided for the chip 10 through the electrical contacts 05 formed on the inactive side being electrically mounted thereon without via bonding wires.

### Embodiments of IC Chip Package for Packaging Two or More Stacked Chips

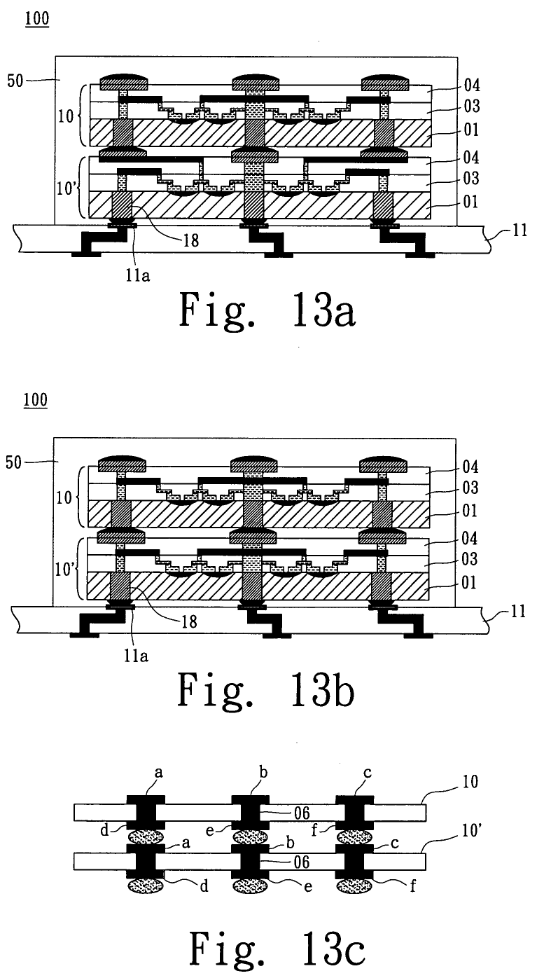

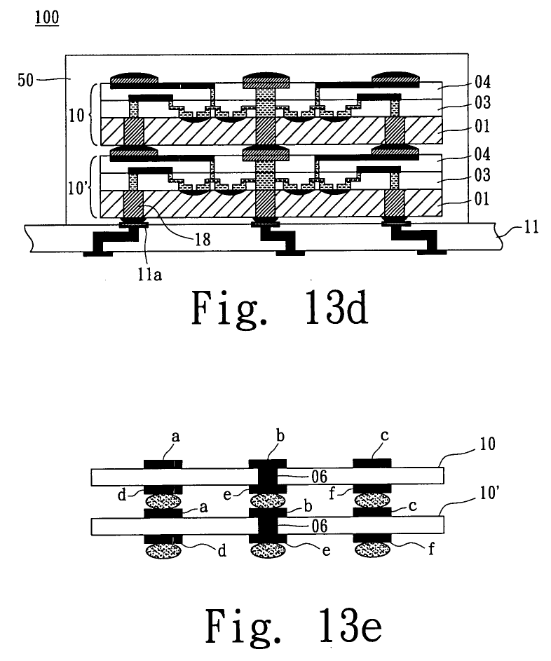

Three preferred embodiments of IC chip package 100 packaged with two stacked chips of the present invention are illustrated in FIGS. 13a, 13b and 13d respectively, each kind of IC chip package 100 of the present invention at least comprises two chips 10 and 10′ stacked together each having one or more half-tunneling electrical contacts 18 penetrating a processed substrate 01 for forming one or more electrical contacts 05 on both inactive side and active side of the chip 10, a circuited substrate (or other element) 11 having a top and bottom surfaces on which conductive circuit patterns formed with electrical contacts 11a are respectively laid-out for providing the lowermost chip 10 electrically mounted thereon and an encapsulated means 50 for covering the two stacked chips 10 to constitute a package structure of the IC chip package 100.

Further, to minimize the assembled volume of IC chip package 100 illustrated in FIG. 13a, the package structure of the IC chip package 100 is packaged in such a way that the chips 10 and 10′ are easily stacked together and the electrical contacts 05 formed on the inactive side of the topmost chip 10 are electrically connected to the corresponding electrical contacts 05 formed on the active side of the lowermost chip 10′ and the electrical contacts 05 formed on the inactive side of the lowermost chip 10′ are electrically connected to the corresponding electrical contacts 11a of circuited substrate (or other element) 11 without via bonding wires.

Referring to FIGS. 13b and 13c, if the two chips 10 and 10′ are identical structure each is provided with electrical contacts (a), (b) and (c) on the active side and electrical contacts (d), (e) and (f) on the inactive side respectively and formed a structure in such a way that the electrical contacts (d), (e), and (f) on the inactive side of the chip 10 are electrically connected to the electrical contacts (a), (b), and (c) on the active side of the chip 10 via the circuits 06 in the chip 10, respectively.

While the two chips 10 and 10′ are stacked together, the electrical contacts (a), (b) and (c) on the active side of the topmost chip 10 are then directly constituted an electrical connection to the electrical contacts (d), (e) and (f) on the inactive side of the lowermost chip 10′ as shown in FIG. 13c, respectively.

In other words, the IC chip package 100 of the present invention illustrated in FIG. 13b provides a minimized stacked package structure to make the chips 10 and 10′ stacked in parallel electrical connection without via bonding wires.

However, if each chip 10 or 10′ illustrated in FIGS. 13d and 13e is only provided with electrical contacts (b) on the active side is electrically connected to the electrical contacts (e) on the inactive side of the chip 10 or 10′ via the circuits 06 in the chip 10 or 10′ and electrical contacts (a) and (c) on the active side are, not directly but indirectly, electrically connected to the electrical contacts (d) and (f) on the inactive side of the chip 10 or 10′, respectively.

When the two chips 10 and 10′ are stacked, only the electrical contacts (b) on the active side of the topmost chip 10 is then directly constituted an electrical connection to the electrical contacts (e) on the inactive side of the lowermost chip 10′ as shown in FIG. 13e, respectively.

In other words, the IC chip package 100 of the present invention illustrated in FIG. 13d provides a minimized stacked package structure to make the chips 10 and 10′ stacked in serial electrical connection without via bonding wires

### Embodiments of IC Chip Package for Packaging System-In-Package (SIP)

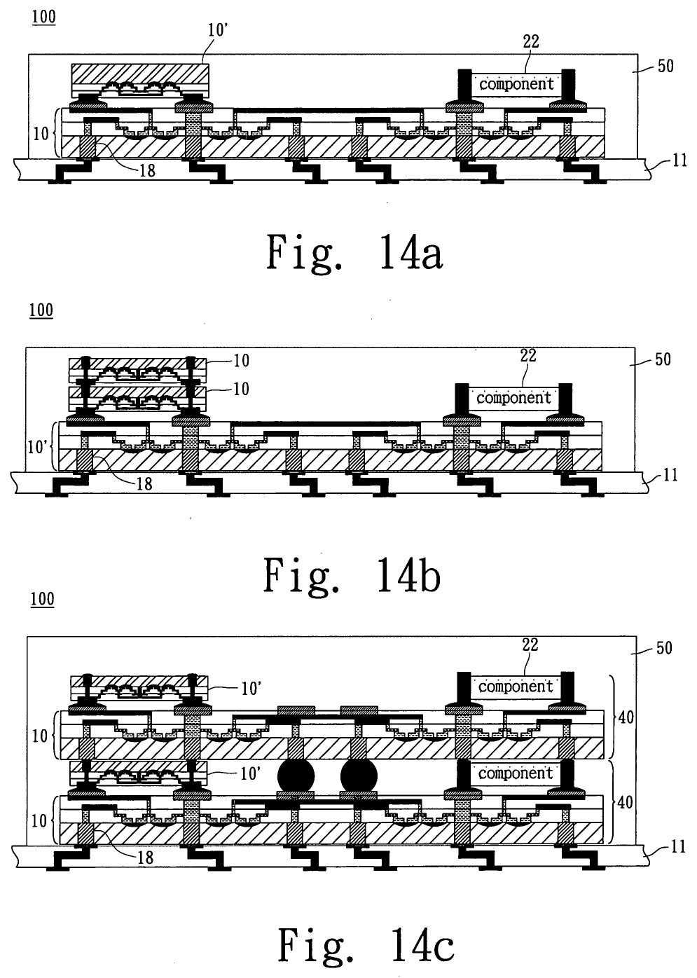

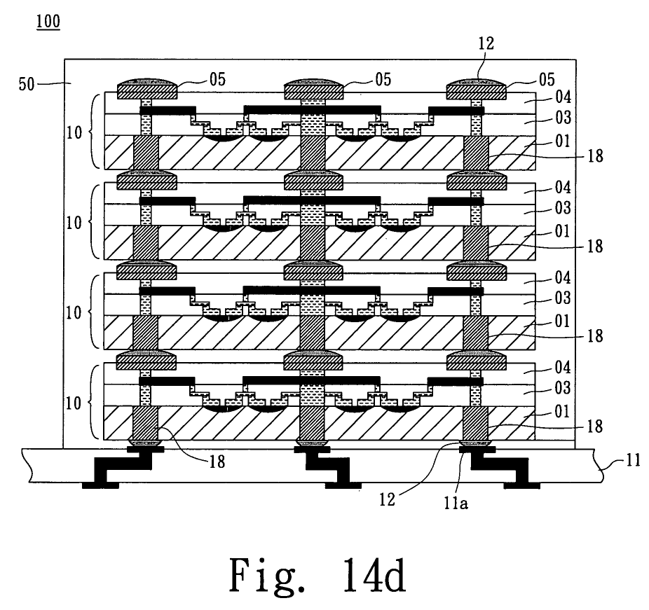

Four preferred embodiments of IC chip package 100 packaged with System-In-Package (SIP) of the present invention are illustrated in FIGS. 14a to 14d respectively, each kind of IC chip package 100 of the present invention at least comprises two or more chips 10 and 10′ stacked together for packaging a System-In-Package each having one or more half-tunneling electrical contacts 18 penetrating a processed substrate 01 for forming one or more electrical contacts 05 on both inactive side and active side of the chip 10 or 10′, a circuited substrate (or other element) 11 having a top and bottom surfaces on which conductive circuit patterns formed with electrical contacts 11a are respectively laid-out for providing the lowermost chip 10 (or 10′) electrically mounted thereon and an encapsulated means 50 for covering the chips 10 and 10′ to constitute a SIP package structure of the IC chip package 100.

As shown in FIG. 14a, a SIP packaged IC chip package 100 of the present invention provides a chip 10 being electrically connected to a circuited substrate 11 and a chip 10′ or further connected to an electronic component 22 via the electrical contacts on the active side and the inactive side of the chip 10, respectively.

Further, take the chip 10 having an operational function different from that of the chip 10′ as an example, e.g., the chip 10 selected from a CPU, the chip 10′ selected from a memory chip and the electronic component 22 selected from passive elements such as resistor or capacitor are packaged together as a SIP packaged IC chip package 100 of the present invention.

In this case, the SIP packaged IC chip package 100 of the present invention is advantageous to shorten the transmission distance between the CPU, the memory chip and the passive elements and to increase the variety of the SIP packaged structure.

As shown in FIG. 14b, a SIP packaged IC chip package 100 of the present invention provides a pair of the same chips 10 stacked together and electrically connected to each other via the electrical contacts on the active side and the inactive side of the chips 10, and then another chip 10′ is electrically connected to a circuited substrate 11 and the two stacked chips 10 or further connected to an electronic component 22 via the electrical contacts on the active side and the inactive side of the chip 10′, respectively.

As shown in FIG. 14c, a SIP packaged IC chip package 100 of the present invention provides two stacked SIP electronic devices 40 being integrated into an IC chip package 100, wherein each SIP electronic device 40 at least has a chip 10′ electrically connected to a different chip 10 via the electrical contacts on the active side and the inactive side of the chips 10 and 10′, and the two stacked SIP electronic devices 40 when stacked together is constituted an electrical connection through the electrical contacts on the active side and the inactive side of the chips 10 and 10′ respectively having installed on the topmost SIP electronic device 40 and the lowermost SIP electronic device 40.

As shown in FIG. 14d, a SIP packaged IC chip package 100 of the present invention provides four identical chips 10 integrated into an IC chip package 100, wherein the four identical chips 10 are electrically connected to each other via the electrical contacts on the active side and the inactive side of the chips 10 and assembled on a common circuited substrate 11 in a stacked manner.

Take the chips 10 selected from a memory IC as an example, a plurality of memory chips may be integrated into a SIP packaged IC memory package 100 of the present invention to substantially minimize the space.

### Embodiments of IC Chip Package for Packaging Semiconductor Elements

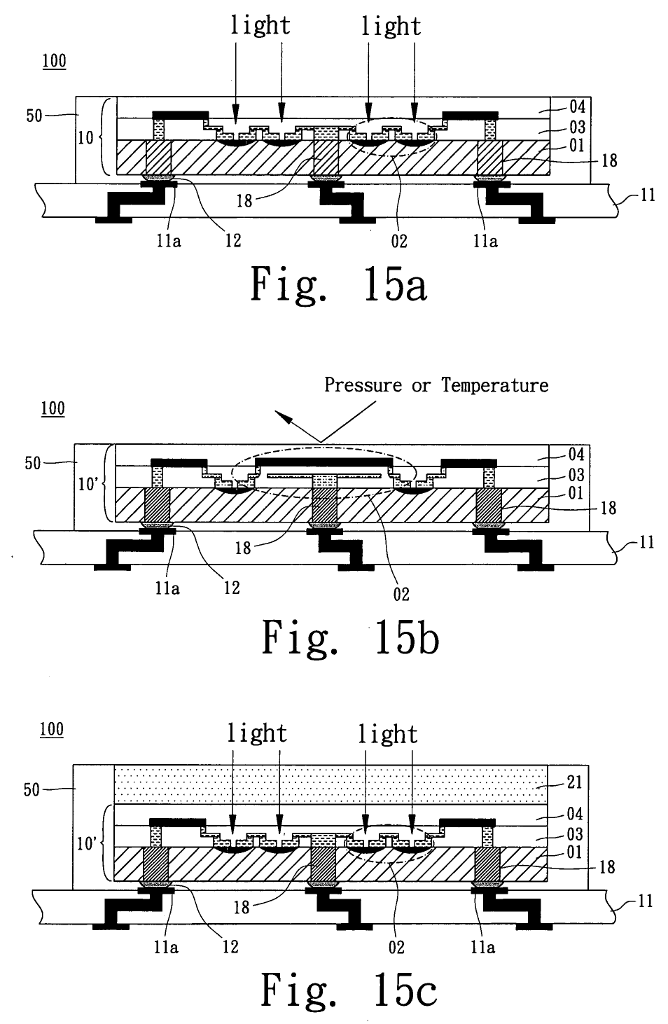

As shown in FIG. 15a, a chip 10 selectively formed with an electro-optical element 02 is packaged with a circuited substrate 11 and an encapsulated means 50 to constitute a package structure of the IC chip package 100 of the present embodiment, wherein the chip 10 is provided with one or more half-tunneling electrical contacts 18 having an end exposed on the inactive side of a processed substrate 01 for being electrically connected to the electrical contact 11a of the circuited substrate 11 by the solder material 12.

Since the inactive side of the chip 10 is electrically connected to the circuited substrate 11, the advantages obtained from the kind of IC chip package 100 is that on upper surface of the electro-optical element 02 formed on the chip 10 is prevented from being blocked or hindered by any other circuits, electronic elements or substrates.

As shown in FIGS. 15b and 15c, take one or more pressure sensor elements or temperature sensor elements 02 formed on a chip 10′ as an example, when the chip 10′ is packaged as an IC chip package 100 of the present invention, due to no circuits, electronic elements or substrates blocked or hindered over the electro-optical element 02 of the chip 10′, the IC chip package 100 when used as a pressure sensor or temperature sensor may minimize in size and promote the precision operated in application.

Especially, a transparent material 21 such as a glass may be covered over the active side of the chip 10′ to protect the electro-optical element 02 of the chip 10′ from wetting and dirty and keep the chip 10′ packaged in the IC chip package 100 always operated in good state.

The present invention has been described with a preferred embodiment thereof and it is understood that many changes and modifications to the described embodiment can be carried out without departing from the scope and the spirit of the invention that is intended to be limited only by the appended claims.

What is claimed is:

1. An IC chip package at least comprises a chip, a circuited substrate having a top and bottom surfaces on which conductive circuit patterns formed with electrical contacts respectively laid-out for providing the chip electrically mounted thereon, and an encapsulated means for covering the chip to constitute a package structure, characterized in that the chip has a processed substrate with an active side and an inactive side and one or more half-tunneling electrical contacts penetrating the processed substrate, wherein each half-tunneling electrical contact of the chip has a first end exposed on the inactive side of the processed substrate and formed as an electrical contact on the inactive side of the chip and a second end exposed on the active side of the processed substrate and electrically connected to a circuit formed inside the chip.

2. The IC chip package as described in claim 1, wherein the electrical contacts on the inactive side of the chip are electrically connected to the corresponding electrical contacts of the circuited substrate without via bonding wires.

3. The IC chip package as described in claim 1, wherein on the active side of the chip has one or more electrical contacts which are electrically connected to the corresponding electrical contacts of the circuited substrate without via bonding wires.

4. The IC chip package as described in claim 2, further comprising a circuited substrate for providing the chip electrically mounted thereon, and on the active side of the chip has one or more electrical contacts which are electrically connected to the corresponding electrical contacts of the circuited substrate without via bonding wires.

5. The IC chip package as described in claim 2, wherein on the active side of the chip has one or more electrical contacts which are via bonding wires electrically connected to the corresponding electrical contacts of the circuited substrate.

6. The IC chip package as described in claim 2, further comprising an electronic element or a transparent material is installed over the chip and the circuited substrate.

7. The IC chip package as described in claim 6, wherein the chip is formed with one or more electro-optical elements.

8. The IC chip package as described in claim 7, wherein the electro-optical element formed on the chip is a pressure sensor element or a temperature sensor element.

9. An IC chip package at least comprises two stacked chips, a circuited substrate having a top and bottom surfaces on which conductive circuit patterns formed with electrical contacts respectively laid-out for providing the lowermost chip electrically mounted thereon, and an encapsulated means for covering the stacked chips to constitute a package structure, characterized in that each chip has a processed substrate with an active side and an inactive side and one or more half-tunneling electrical contacts penetrating the processed substrate for forming one or more electrical contacts on both inactive side and active side of the chip, wherein one or more electrical contacts formed on the inactive side of the topmost chip are electrically connected to the corresponding electrical contact(s) formed on the active side of the lowermost chip, and wherein the electrical contacts formed on the inactive side of the lowermost chip are electrically connected to the corresponding electrical contacts of the circuited substrate without via bonding wires.

10. The IC chip package as described in claim 9, wherein the two chips are stacked together in parallel electrical connection without via bonding wires.

11. The IC chip package as described in claim 9, wherein the two chips are stacked together in serial electrical connection without via bonding wires.

12. An IC chip package at least comprises a first chip provided for one or more second chips or electronic components electrically connected thereon for packaging a System-In-Package, a circuited substrate having a top and bottom surfaces on which conductive circuit patterns formed with electrical contacts respectively laid-out for providing the first chip electrically mounted thereon, and an encapsulated means for covering the first chips and the second chip(s) and/or the electronic component(s) to constitute a SIP package structure, characterized in that each chip has a processed substrate with an active side and an inactive side and one or more half-tunneling electrical contacts penetrating the processed substrate for forming one or more electrical contacts on both inactive side and active side of the chip, wherein the electrical contacts on the inactive side of the second chip(s) is electrically connected to the electrical contacts on the active side of the first chip, and wherein the electrical contacts formed on the inactive side of the first chip are electrically connected to the corresponding electrical contacts of the circuited substrate without via bonding wires.

13. The IC chip package as described in claim 12, wherein the first chip is a CPU and the second chip(s) is a memory chip.

14. The IC chip package as described in claim 12, wherein both the first chip and the second chip(s) are memory chips.

15. The IC chip package as described in claim 13, wherein the electronic component is a resistor or a capacitor.
